(19) United States
(12) Patent Application Publication
(10) Pub. No.: US 2026/0271662 A1
(43) Pub. Date: Sep. 10, 2026

(54) FRONT OPENING UNIFIED POD FOR CONTAINING SQUARE SUBSTRATES AND CIRCULAR SUBSTRATES

(71) Applicant: STEK CO., LTD., New Taipei City (TW)

(72) Inventor: Ming-Sheng Chen, New Taipei City (TW)

(21) Appl. No.: 19/188,031

(22) Filed: Apr. 24, 2025

(30) Foreign Application Priority Data
Mar. 7, 2025 (TW) 114108483

(51) Int. Cl. H01L 21/673

(52) U.S. Cl. CPC H10P 72/1921; H10P 72/1922

(57) ABSTRACT

A front opening unified pod includes a shell, a door plank and a support unit. The shell includes a top panel, a bottom panel, a rear panel and two lateral panels connected to one another. The top, bottom, rear and lateral panels together provide an interior space that includes a front opening. The door plank is operable to close the front opening. The support unit includes two lateral racks attached to the lateral panels in the interior space and a rear rack attached to the rear panel rear panel in the interior space.

### BACKGROUND OF INVENTION

### 1. Field of Invention

The present invention relates to semiconductor and, more particularly, to a front opening unified pod for containing for containing square substrates and circular substrates.

### 2. Related Prior Art

Substrates such as wafers or glass substrates are contained in a pod during storage or transportation in a manufacturing process to maintain the quality of semiconductor products made of the substrates. For example, a front opening unified pod (“FOUP) is used to contain circular wafers. A panel FOUP is used to contain square panels.

The FOUP cannot be used to contain square panels. The panel FOUP cannot be used to contain circular wafers. Hence, various pods must be used for various substrates. Accordingly, the cost of purchasing various pods is relatively high, and the practice of using various pods is troublesome.

Therefore, the present invention is intended to obviate or at least alleviate the problems encountered in the prior art.

### SUMMARY OF INVENTION

It is the primary objective of the present invention to provide a FOUP for containing square substrates and circular substrates.

To achieve the foregoing objective, the front opening unified pod includes a shell, a door plank and a support unit. The shell includes a top panel, a bottom panel, a rear panel and two lateral panels connected to one another. The top, bottom, rear and lateral panels together provide an interior space that includes a front opening. The door plank is operable to close the front opening. The support unit includes two lateral racks attached to the lateral panels in the interior space and a rear rack attached to the rear panel rear panel in the interior space.

In another aspect, each of the lateral and rear racks includes fins for supporting the square and circular substrates.

Other objectives, advantages and features of the present invention will be apparent from the following description referring to the attached drawings.

### BRIEF DESCRIPTION OF DRAWINGS

The present invention will be described via detailed illustration of embodiments referring to the drawings wherein:

FIG. 1 is an exploded view of a FOUP according to an embodiment of the present invention;

FIG. 2 is another exploded view of the FOUP shown in FIG. 1;

FIG. 3 is a front view of the FOUP shown in FIG. 1;

FIG. 4 is a perspective view of a lateral rack of the FOUP depicted in FIG. 1;

FIG. 5 is a perspective view of a rear rack of the FOUP shown in FIG. 1;

FIG. 6 is an enlarged, partial and cross-sectional view of the lateral rack shown in FIG. 4;

FIG. 7 is a partial and perspective view of a lateral rack of a FOUP according to another embodiment of the present invention;

FIG. 8 is partial and perspective view of a rear rack of a FOUP according to another embodiment of the present invention;

FIG. 9 is partial and perspective view of a lateral rack of a FOUP according to another embodiment of the present invention;

FIG. 10 is an enlarged, partial and cross-sectional view of the lateral rack taken along a line 10-10 shown in FIG. 9;

FIG. 11 is partial and perspective view of a lateral rack of a FOUP according to another embodiment of the present invention;

FIG. 12 is an enlarged, partial and cross-sectional view of the lateral rack taken along a line 12-12 shown in FIG. 11;

FIG. 13 is partial and perspective view of a lateral rack of a FOUP according to another embodiment of the present invention;

FIG. 14 is an enlarged, partial and cross-sectional view of the lateral rack taken along a line 14-14 shown in FIG. 13;

FIG. 15 is a cross-sectional view of the FOUP shown in FIG. 1, containing a square substrate; and

FIG. 16 is a cross-sectional view of the FOUP shown in FIG. 1, containing a circular substrate.

### DETAILED DESCRIPTION OF EMBODIMENTS

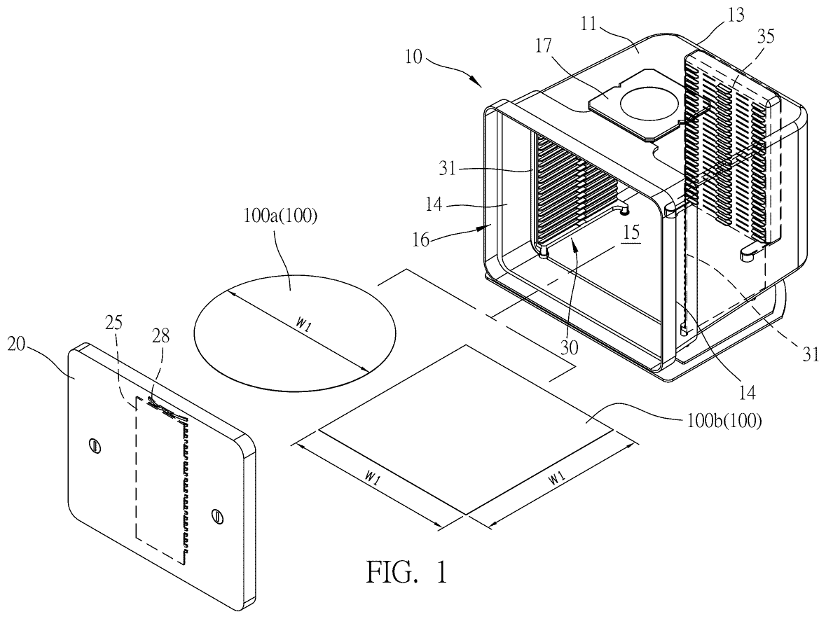

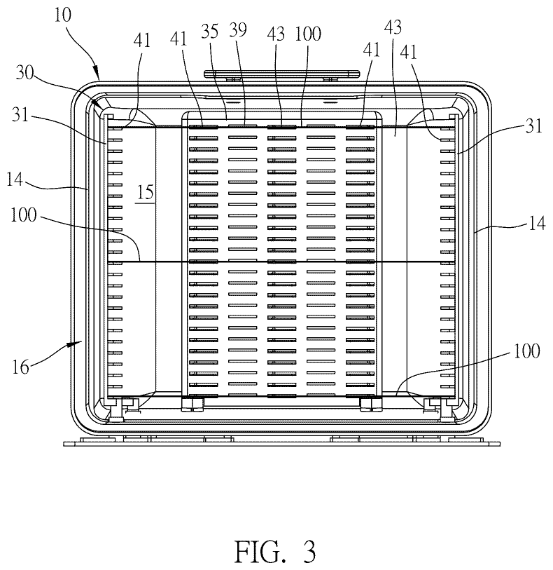

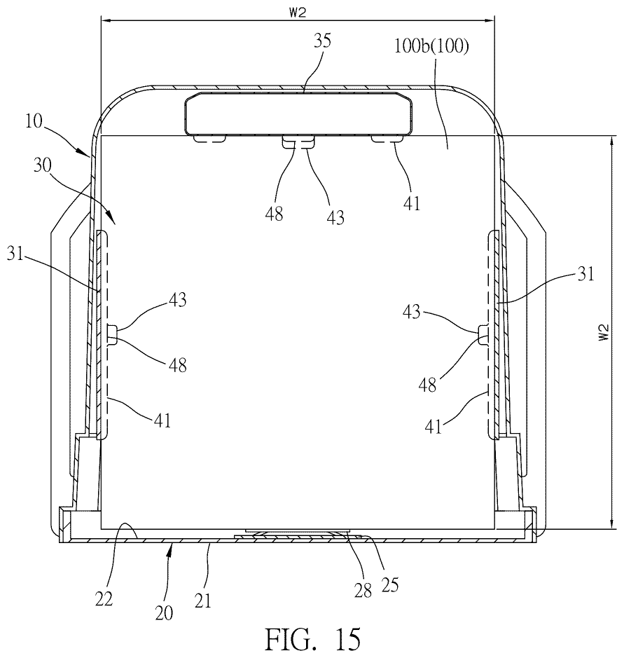

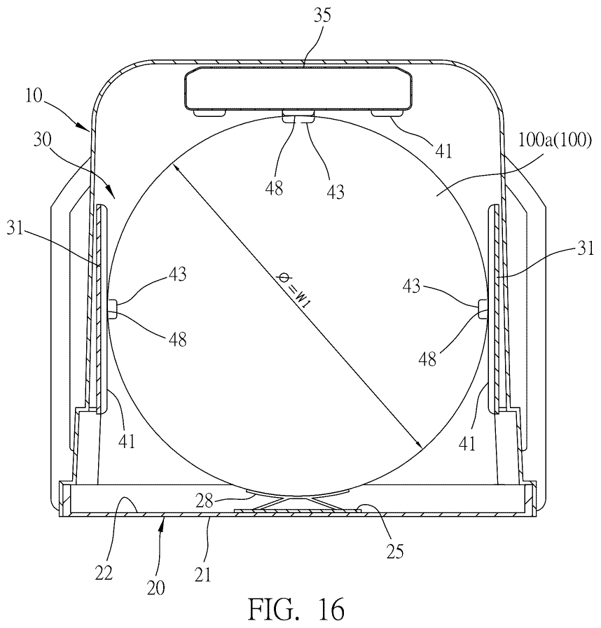

Referring to FIGS. 1 through 6, a front opening unified pod (“FOUP”) includes a shell 10, a door plank 20 and support unit 30 according to a first embodiment of the present invention. The FOUP is operable to contain substrates 100 such as square substrates 100b (FIG. 15) and circular substrates 100a (FIG. 16).

Shell 10 includes a top panel 11, a bottom panel 12, a rear panel 13 and two lateral panels 14. Rear panel 13 is located between and connected to top panel 11 and bottom panel 12, and so are lateral panels 14. Top panel 11, bottom panel 12, rear panel 13, lateral panels 14 together define an interior space 15 that includes a front opening 16. Substrates 100 are insertable into or moved from interior space 15 via the front opening 16. Preferably, top panel 13 is formed with a handle 17 maneuverable by a robot (not shown).

Preferably, top panel 11, bottom panel 12, rear panel 13, lateral panels 14 are made in one piece. In another embodiment, shell 10 includes a rear opening (not shown). The rear opening is closed by attaching rear panel 13 to top panel 11, bottom panel 12 and lateral panels 14. The rear opening is opened by removing rear panel 13 from top panel 11, bottom panel 12 and lateral panels 14.

Door plank 20 is operable to close front opening 16. Door plank 20 is equipped a latch mechanism 23 operable to lock door plank 20 on shell 10, thereby closing front opening 16. Door plank 20 is formed with an internal face 22 to which a substrate holder 25 is attached. Substrate holder 25 includes leaf springs 28. Each leaf spring 28 is operable to press an edge of a substrate 100. Leaf springs 28 are shaped according to circular substrates 100a or square substrates 100b. In another embodiment, each leaf spring 28 can include a recess (not shown) for receiving the edge of the corresponding substrate 100.

Support unit 30 includes two lateral racks 31 and a rear rack 35. Each lateral rack 31 is attached to an internal face of a corresponding lateral panel 14 so that lateral racks 31 are inserted in interior space 15. Rear rack 35 is attached to an internal face of rear panel 13 so that rear rack 35 is inserted in interior space 15. Lateral racks 31 and rear rack 35 together support substrates 100 horizontally.

It should be noted that lateral racks 31 can be replaced with racks identical to rear rack 35, i.e., support unit 30 includes three racks 35. I should be noted that rear rack 35 can be replaced with a rack identical to lateral racks 31, i.e., support unit 30 includes three racks 31.

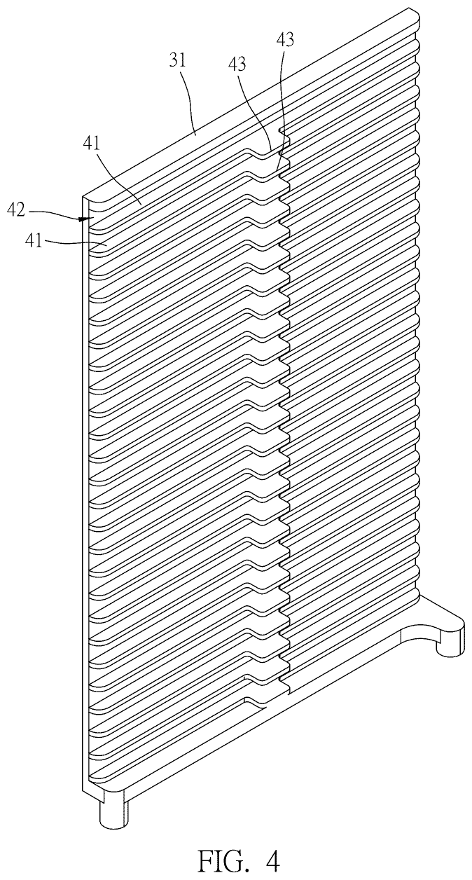

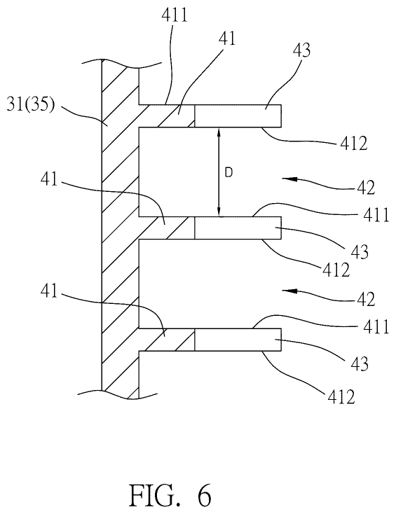

Referring to FIGS. 4 and 6, each lateral rack 31 includes fins 41 and tabs 43. Fins 41 extend horizontally. Any two adjacent fins 41 are separated from each other by a gap 42 of a depth D. Each fin 41 includes an upper face 411 and a lower face 412. Upper face 411 of each fin 41 is for contact with a lower face of a substrate 100. Preferably, each tab 43 extends from a middle section of an edge of a corresponding fin 41. Each fin 41 includes an upper face extending in a same plane with an upper face of a corresponding tab 43.

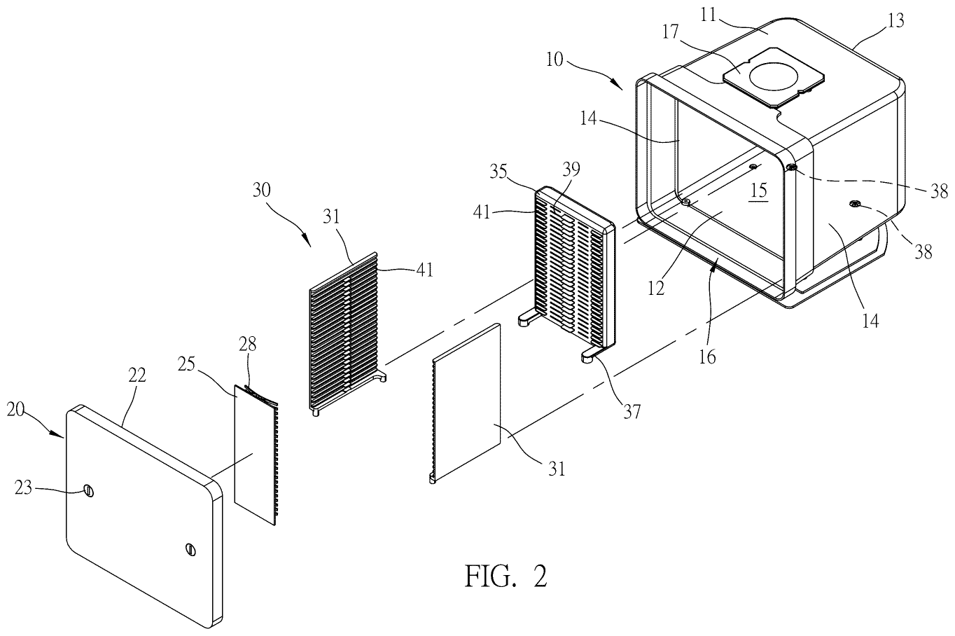

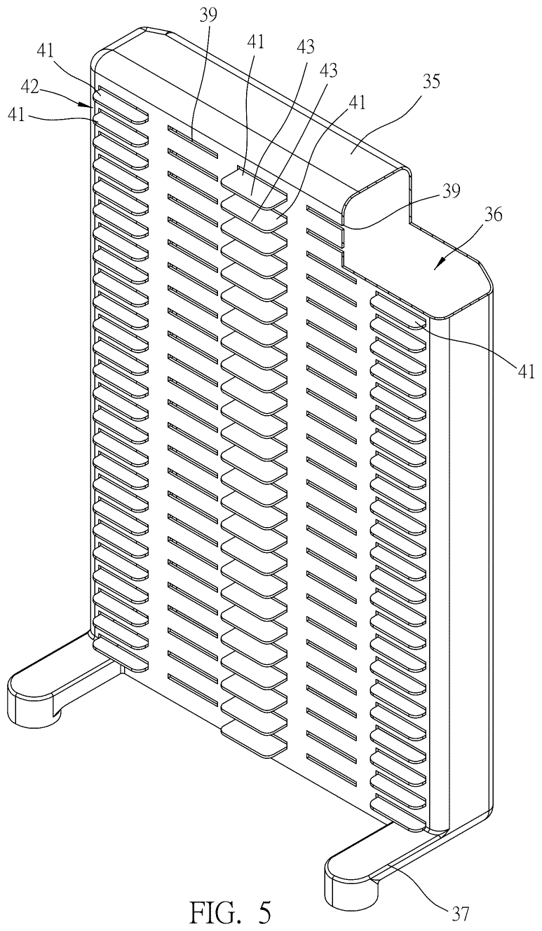

Referring to FIG. 5, rear rack 35 includes a chamber 36, two conduits 37 in communication with chamber 36, and slots 39 in communication with chamber 36. Slots 39 are made in a front panel of rear rack 35. Bottom panel 14 is equipped with two valves 38 (FIG. 2). Each valve 38 is in communication with a corresponding conduit 37 when rear rack 35 is attached to rear panel 13. Thus, air is allowed to go into interior space 15 from exterior of shell 10 via valves 38, conduits 37, chamber 36 and slots 39.

Preferably, rear rack 35 includes lateral rows of fins 41 and a middle row of fins 41. A slot 39 is located between a corresponding fin 41 in each of the lateral rows and a corresponding fin 41 in the middle row. Each fin 41 in the first lateral row, a corresponding fin 41 in the middle row and a corresponding fin 41 in the second lateral row are arranged in a same horizontal line. Each fin 41 in the middle row is formed with a tab 43.

In use, each fin 41 of the first lateral rack 31, a corresponding fin 41 of the second lateral rack 31 and a corresponding line of fins 41 of rear rack 35 together support a substrate. Tabs 43

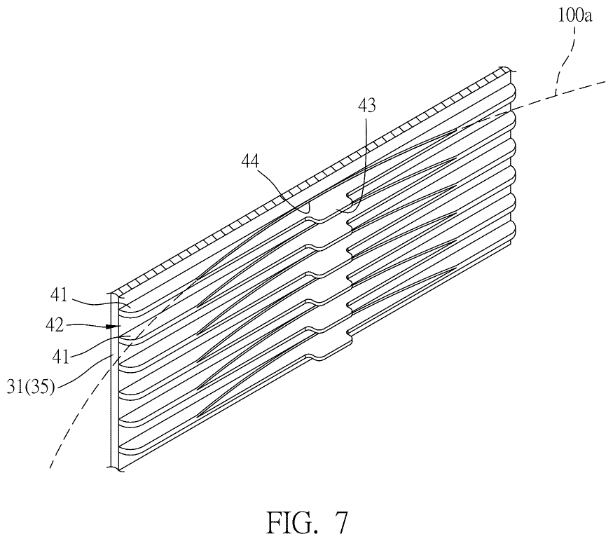

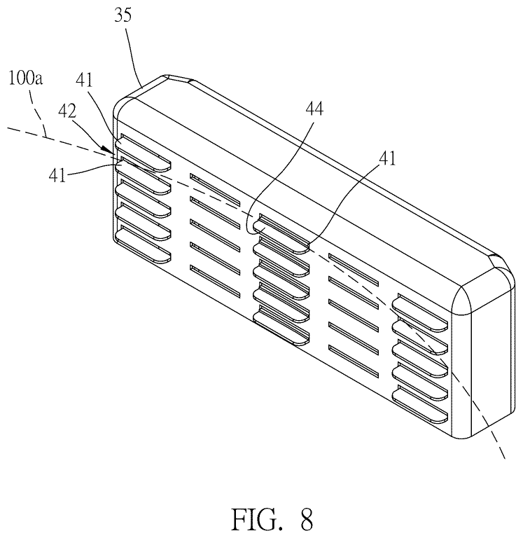

Referring to FIGS. 7 and 8, according to a second embodiment of the present invention, each fin 41 of each lateral rack 31 includes a recess 44 in compliance with a section of a circle, and so does each fin 41 in the middle row of rear rack 35. Each recess 44 is useful in containing a portion of a circular substrate 100a. Accordingly, the upper face of each fin 41 extends higher than the upper face of a corresponding tab 43.

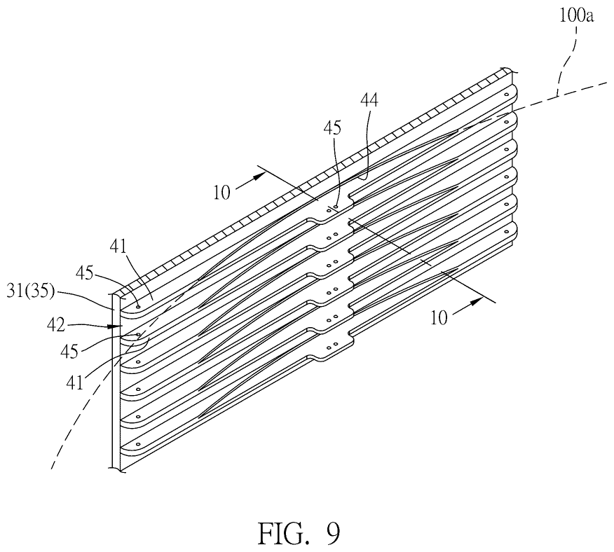

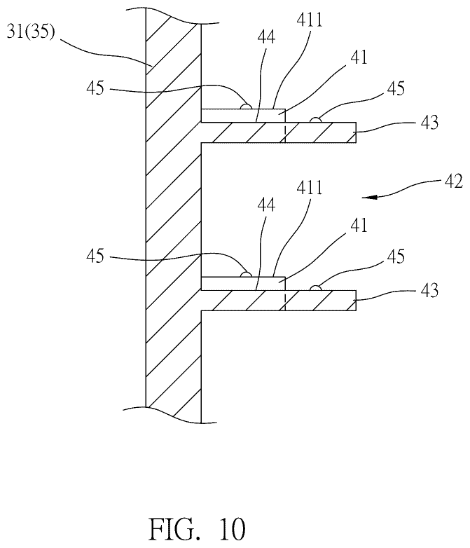

Referring to FIGS. 9 and 10, there is a lateral rack 31 according to a third embodiment of the present invention. The third embodiment is identical to the second embodiment except that each fin 41 is formed with two bosses 45 out of recess 44 and two bosses in recess 44. Bosses 45 out of recess 44 are for contact with a square substrate 100b. Bosses 45 in recess 44 are for contact with a circular substrate 100a. Bosses 45 in recess 44 do not extend beyond upper face 411 of each fin 41.

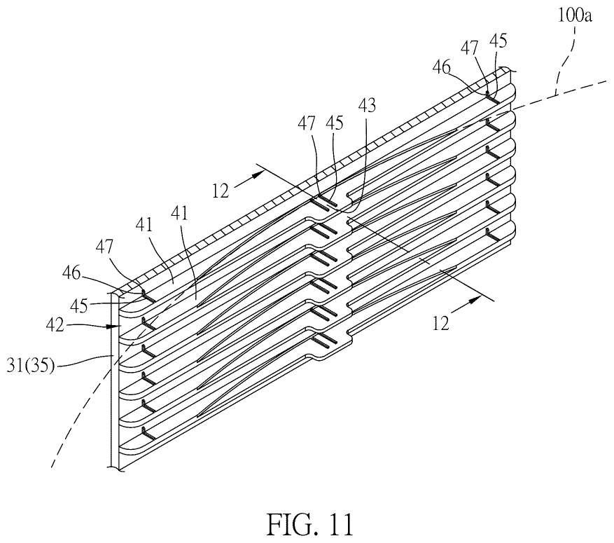

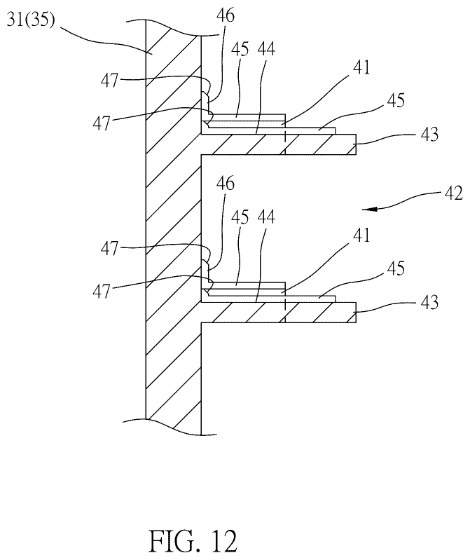

Referring to FIGS. 11 and 12, there is a lateral rack 31 according to a fourth embodiment of the present invention. The fourth embodiment is identical to the second embodiment except for two things. Firstly, the bosses 45 are elongated bosses. Secondly, an elongated boss 46 extends from a corresponding elongated boss 45. Each elongated boss 46 includes a chamber 47 at an end to facilitate movement of an edge of a substrate 100 to elongated bosses 45 past elongated bosses 46. Elongated bosses 46 reduce total area of contact of the edge of a substrate 100 with each lateral rack 31.

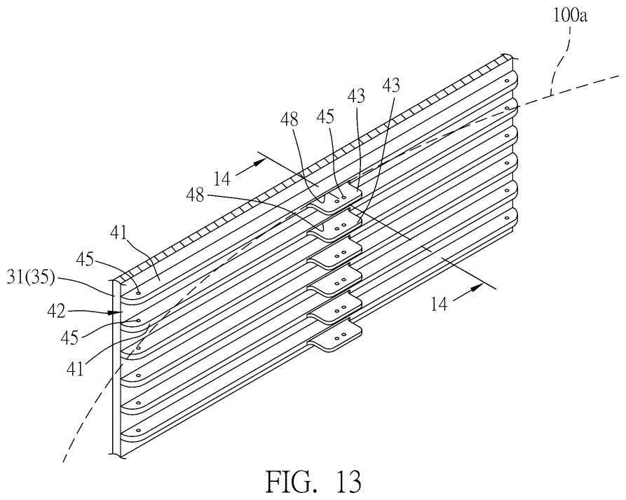

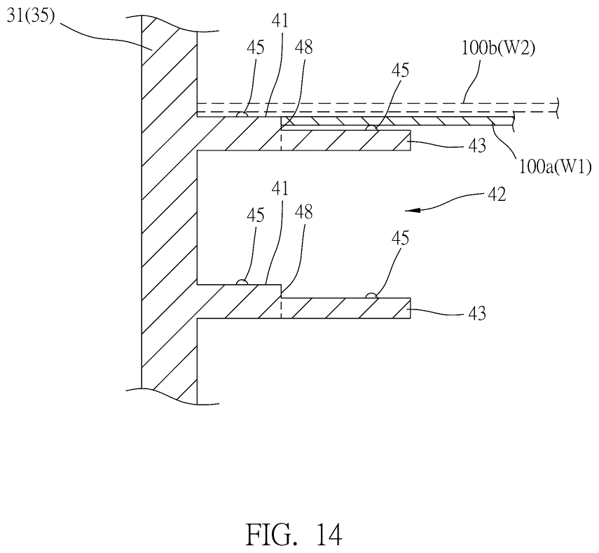

Referring to FIGS. 13 and 14, there is a lateral rack 31 in accordance with a fifth embodiment of the present invention. The fifth embodiment is identical to the third embodiment except for that each fin 41 includes a recess 48 instead of recess 44. It should be noted that the diameter of circular substrate 100a in the fifth embodiment is shorter than the diameter of circular substrate 100a in the third embodiment. The recess 48 can be cut only in a corresponding tab 43, not in any other portion of a corresponding fin 41. Each circular substrate 100a includes a diameter W1. Each square substrate 100b includes a width W2. For example, diameter W1 of each square substrate 100 a is 300 mm, and width W2 of each square substrate 100 b is 310 mm. The distance between two lateral racks 31 is 310 mm corresponding to width W2 of each square substrate 100b (FIG. 15). The distance between an edge of each fin 41 of a lateral rack 31 and an edge of a corresponding fin 41 of another lateral rack 31 is 300 mm corresponding to diameter W1 of each circular substrate 100b.

The present invention has been described via the illustration of the embodiments. Those skilled in the art can derive variations from the embodiments without departing from the scope of the present invention. Therefore, the embodiments shall not limit the scope of the present invention defined in the claims.

1. A front opening unified pod comprising:
a shell comprising a top panel, a bottom panel, a rear panel and two lateral panels connected to one another, wherein the top, bottom, rear and lateral panels together provide an interior space that comprises a front opening;
a door plank for closing the front opening; and
a support unit comprising two lateral racks attached to the lateral panels in the interior space and a rear rack attached to the rear panel rear panel in the interior space.

2. The front opening unified pod according to claim 1, wherein each of the lateral and rear racks comprises fins separated from each other, wherein each of the fins of one of the lateral racks, a corresponding one of the fins of the remaining one of the lateral racks and a corresponding one of the fins of the rear rack are arranged along a same horizontal line.

3. The front opening unified pod according to claim 2, wherein each of the fins comprises a recess in a middle portion compliant to a section of an edge of a circular substrate, wherein the recesses of the fins arranged along each of the horizontal lines receive portions of the edge of the corresponding circular substrate.

4. The front opening unified pod according to claim 1, wherein each of the lateral and rear racks comprises fins separated from each other, wherein each of the fins of one of the lateral racks, a corresponding one of the fins of the remaining one of the lateral racks and a corresponding one of the fins of the rear rack are arranged along a same horizontal line, wherein each of the fins comprises a recess in a middle portion compliant to a section of an edge of a circular substrate, wherein the recesses of the fins arranged along each of the horizontal lines receive portions of the edge of the corresponding circular substrate.

5. The front opening unified pod according to claim 2, wherein each of the fins comprises a tab extending from a middle section.

6. The front opening unified pod according to claim 5, wherein each of the fins comprises an upper face extending higher than an upper face of the tab thereof.

7. The front opening unified pod according to claim 2, wherein each of the fins comprises bosses.

8. The front opening unified pod according to claim 2, wherein each of the fins comprises elongated bosses for contact with an edge of a substrate, thereby reducing total area of contact of the substrate with each of the lateral and rear racks.

9. The front opening unified pod according to claim 8, wherein each of the elongated bosses comprises a chamber at an upper end to facilitate smooth movement of the substrate to the corresponding fin.

10. The front opening unified pod according to claim 2, wherein the rear rack comprises a chamber, a conduit in communication with the chamber, and slots in communication with the chamber, wherein air is allowed to go into the interior space through the conduits, the chamber and the slots.

11. The front opening unified pod according to claim 1, wherein one of the lateral and rear racks comprises first and second rows of fins, wherein each of the fins in the first row and a corresponding one of the fins in the second row are arranged along a horizontal line.

12. The front opening unified pod according to claim 1, wherein one of the lateral and rear racks comprises first and second lateral rows of fins and a middle row of fins, wherein each of the fins in the first lateral row, a corresponding one of the fins in the second lateral row and a corresponding one of the fins in the middle row are arranged along a horizontal line.
